(19) United States
(12) Patent Application Publication
(10) Pub. No.: US 2017/0363789 A1
(43) Pub. Date: Dec. 21, 2017

(54) IR REFLECTIVE FILM

(71) Applicant: BASF SE, Ludwigshafen (DE)

(72) Inventors: Martin STALDER, Oberwill (CH); Benjamin GALLINET, Muttenz (CH); Fabian LUETOLF, Magden (CH); Guilaume BASSET, Huningue (FR); Rolando FERRINI, Bern (CH); Patrice BUJARD, Courtepin (CH); Adrian VON MUEHLENEN, Zofingen (CH); Andreas HAFNER, Gelterkinden (CH)

(21) Appl. No.: 15/539,362

(22) PCT Filed: Dec. 18, 2015
(86) PCT No.: PCT/IB2015/059762

§ 371 Date: Jun. 23, 2017

(30) Foreign Application Priority Data
Dec. 23, 2014 (EP) 14199981.3

(51) Int. Cl. G02B 5/28; G02B 1/118; E06B 9/24; H01L 31/0216; C23C 14/58; C23C 14/20; C23C 14/06

(52) U.S. Cl. CPC G02B 5/282; E06B 9/24; G02B 1/118; E06B 2009/2417; C23C 14/0629; C23C 14/5873; C23C 14/20; H01L 31/02168

(57) ABSTRACT

A translucent or transparent film or sheet device shows angular-independent IR reflectance, which comprises a substrate (1) covered with a layer of a dielectric high refractive index material (4) containing a thin metallic layer (3) embedded in said material, and a further layer (5) of translucent or transparent material covering said layer (4) of dielectric high refractive index material, characterized in that the embedded metal layer (3) is periodically interrupted with a periodicity of 50 to 800 nm such that metal covers at least 70% of the substrate area. The device may advantageously be integrated into a window, a glass facade element or especially onto a photovoltaic (PV) device, where it reduces the fraction of IR radiation passing into the building, or reduces heat take-up and thus lowers the operating temperature and improves the efficiency of the PV cell.

The invention relates to the management of radiation, and more specifically to a device or film providing high transparency and transmission of visible light and high reflection of infrared light, typically from solar radiation. The device may advantageously be integrated into a window, a glass facade element or especially onto a photovoltaic (PV) device, where it reduces the fraction of IR radiation passing into the building, or reduces heat take-up and thus lowers the operating temperature and improves the efficiency of the PV cell.

Photovoltaic cells such as silicon solar cells typically heat up under solar light illumination, which leads to a significant loss of efficiency. Present invention provides a protective foil which can be mounted on PV cells order to lower the unwanted heating generated by the infrared part of solar light.

Heat-reflecting structures containing a layer of a highly refractive material such as ZnS are described in EP-A-1767964 and WO2012/147052 as a zero-order diffractive filter; it is proposed for IR-management purposes in solar-control applications where the transmission of solar energy into a building or a vehicle has to be controlled. The functionality of the filter is based on certain grating structures within the highly refractive layer.

Some commercial heat management films comprise multilayers including silver and/or dielectric layers providing a certain reflection depending on the wavelength. U.S. Pat. No. 7,727,633 and U.S. Pat. No. 7,906,202 describe a combination of two optical layers, which help to reject solar light in the infrared wavelength range: The first is a polymeric multilayer film which provides a high reflectivity for a limited wavelength range in the infrared; this film is composed of tens or hundreds of sub-layers (Bragg reflector) resulting in an angle sensitive reflection band, which moves toward the visible as the incidence angle of the light is increased. The second layer involves nanoparticles, which absorb light in the infrared wavelength range.

US-A-2011-203656 describes some metallic nanostructures on a transparent polymer substrate for use as a transparent electrode in solar cells or light emitting diodes. WO2004/019083 describes a diffractive grating containing reflective facets, which are partly coated with an electrically conducting material for various applications such as optical telecommunication. G. Mbise et al., Proc. SPIE 1149, 179 (1989), report an angular dependent light transmission through Cr-films deposited on glass under an oblique angle.

WO 2015/007580 describes certain nanostructured surfaces comprising an interrupted metal layer, which are transparent for visible light and show a reflection of infrared radiation strongly dependent on the angle of incidence.

A number of publications describe interference filters using stacks of layers which reflect infrared radiation while transmitting visible light, such as a Fabry-Perot filter containing one or more metallic layers between dielectric layers comprising metal oxides, (U.S. Pat. No. 5,111,329; WO 09/120175; U.S. Pat. No. 5,071,206), or alternating polymer layers (U.S. Pat. No. 7,906,202). The transmittance through a metallic layer may be improved by contacting it with a layer of dielectric material of high refractive index (index matching); an overview is given by Granqvist, Appl. Phys. A 52, 83 (1991).

It has now been found that an improved and largely angular independent reflectance of infrared (IR) radiation may be achieved by introducing periodic interruptions into the metallic layer, and selecting high refractive dielectrics for the layers adjacent to said metallic layer. In consequence, present device comprising one interrupted metal layer may provide an IR reflective effect similar to the one achieved with multiple layer stacks. Alternatively, the present device may be applied as a multilayer stack in order to realize an intensified IR filter effect.

Present invention thus primarily pertains to a translucent or transparent film or sheet comprising a substrate (1) covered with a layer of a dielectric high refractive index material (4) containing a metallic layer (3) embedded in said material, and a further layer (5) of translucent or transparent material covering said layer (4) of dielectric high refractive index material, characterized in that the embedded metal layer (3) is periodically interrupted with a periodicity of 50-800 nm (typically: 100-500 nm, especially 100-300 nm) such that metal covers at least 70%, especially 70 to 99%, of the substrate area (in the following also described as duty cycle of the metal layer being 0.7 or higher, typically from the range 0.7 to 0.99, preferably from the range 0.8-0.95).

The device may advantageously be integrated into a window, a glass facade element or especially onto a photovoltaic (PV) device, where it functions as a protective foil reducing the fraction of IR radiation passing into the building or onto the PV cell. It thus reduces heat take-up and lowers the temperature within the building or the operating temperature of the PV cell, thereby improving its efficiency.

A typical device of the invention is shown in FIG. 1 or 4, each showing a cross-section through the protective film or sheet, which contains the transparent or translucent substrate (1), a thin metal layer (4) between two layers of a dielectric material of high refractive index (3) above and underneath the metal layer, thus providing the optical effect of embedding the thin metal layer into one layer of the dielectric material, further a passivation layer (protective layer, 5) on top of the upper high index refraction layer (side opposite to the substrate). Further, the device may optionally comprise an AR coating (2) on said passivation layer. In a typical installation of the present device, side of layer 4 and optionally 2 faces the sunlight, while the substrate side is turned away from the sunlight (typically towards the interior of the building or towards the PV cell).

Materials commonly used for glazings or protective foils are also useful for the present substrate (1); these materials, such as common crown or flint glass, transparent polymeric materials such as polycarbonate, polyacrylics such as PMMA, polyvinylbutyral, typically have refraction indices close to 1.5, for example from the range 1.45 to 1.65, commonly from the range 1.5 to 1.6. The same class of materials basically may be used for the preparation of the passivation layer (protective layer, 5). Radiation curable polymers have similar refractive properties and may be used in combination with the above materials, e.g. as an embossable coating on the substrate, or as passivation layer or part of said layer.

The layers of dielectric high refractive index (HRI) material (3) embedding the interrupted metallic layer (4) provide a suitable index matching and thus contribute to a good transmission of visible light through the present device. Their refractive index typically is by at least 0.4 higher than the refractive index of the passivation layer (5); typically, the difference of refractive indices of HRI material and passivation layer is from the range 0.4 to 1.0, preferably from the range 0.5 to 0.9. Generally, the refractive index of the HRI material is 1.9 or higher, typically from the range 1.9 to 2.8, preferably from the range 2.0 to 2.6.

Preferred is a film or sheet wherein the periodicity of interruptions in the metal layer (3) within at least one dimension is from the range 100 to 500 nm (most preferably: 100 to 300 nm). The embedded metal layer typically covers 70 to 99%, especially 80 to 95%, of the substrate area.

As apparent from the construction of the present film or sheet device noted above, the plane of the metallic layer generally is parallel to the substrate plane. The thickness of the metal layer (3), typically is from the range 4 to 20 nm, especially 5 to 15 nm. The thickness of the metal layer (3) generally is determined perpendicular to its plane. The metal layer may be flat, thus covering the substrate area indicated by the duty cycle as a layer parallel to the substrate, or the metal layer may be structured by comprising small parts, typically on the edge of interruptions, of its area deviating from parallelism or even perpendicular to the substrate plane, such non-parallel parts typically extending to a length 2-5 times of its thickness; such small parts of the metallic layer, which do not cover more than 10 percent of the substrate surface and typically do not cover more than 1 percent of the substrate surface, may in certain cases pierce one or even both sides of the HRI layer (4); in a preferred embodiment, such non-parallel structures do not pierce that layer, and thus are fully embedded in the HRI material.

The thickness of the layer of HRI material (4) typically is from the range 20 to 50 nm, especially 30-40 nm, on each side of the metal layer. Exceptions are possible where parts of the metallic layer deviate from parallelism with the (curved or preferably flat) substrate plane as described above, where the thickness of the layer of HRI material (4) may be reduced or even may be zero (in case of piercing metallic structures). From a manufacturing point of view, the layer of HRI material (4) may be regarded as 2 layers, one on each side of the metallic layer and each essentially parallel to the substrate, which are in contact with each other where the metallic layer is interrupted.

The metal layer typically comprises a metal selected from silver, aluminum, copper, gold; preferably, it essentially consists of silver, aluminum, copper, gold, especially silver.

The dielectric high refractive index material for the HRI layer (4) is typically selected from metal chalcogenides and metal nitrides, preferably of the metals Al, In, Ga, Si, Sn, Ce, Hf, Nb, Ta, Zn, Ti, Zr, and/or binary alkaline chalcogenides and nitrides of these metals, especially oxides, nitrides, sulphides. Typical materials include oxides and alkoxides of titanium and/or zirconium, titanium dioxide, zirconium dioxide, zinc sulphide, indium oxide, tungsten oxide such as tungsten trioxide, zinc oxide, Ta2O5, LiTaO3, ZrO2, SnN, Si3N4, Nb2O5, LiNbO3, CeO2, HfO2, AlN; especially preferred is ZnS.

The film or sheet according to the invention advantageously carries an additional layer (2) on top of the passivation layer (i.e. on top of further layer 5), which additional layer (2) is an antireflex coating.

Useful antireflex (AR) coatings typically are transparent or translucent porous materials, e.g. comprising suitable dielectric particles such as silicon dioxide or alumina in a suitable binder, such as materials disclosed by Wicht et al., Macromolecular Materials and Engineering 295, 628 (2010).

Advantageously, adjacent layers (1), (3), (4), (5) and optionally (2) each are in direct optical contact with each other, i.e. there are in general no inclusions (of air, bubbles etc.) or other materials included, which might lead to undesired optical effects such as diffraction, diffusion or haze.

The present invention thus further relates to an optical device comprising the translucent or transparent film or sheet of the invention, such as a window, a glass facade element or especially a photovoltaic (PV) device.

Relative terms or conditions such as “high”, “low” or “thin”, as used within the present specification, generally define a property of a material or layer with relation to the same or corresponding property of the adjacent material or layer. Thus, for example, the condition “high refractive index” requires the “dielectric high refractive index material” (4) to possess a refractive index higher than the one of both the substrate (1) and the further layer (5).

The term “surface” as used within the present invention denotes a surface of a material which may be covered by another solid material (such as metal, encapsulating layer etc.), thus forming an internal surface of the construction element, device, photovoltaic cell, solar panel or window pane of the invention, or which forms the outer surface of such construction element.

The term “substrate plane” as used within the present invention denotes the plane of the substrate's macroscopic extension, which carries further layers according to the invention including the interrupted metallic layer. While the substrate may be curved in the macroscopic scale, deviations from flatness in the microscopic scale are negligible, the substrate surface is thus referred to in general as forming a flat plane. The substrate surface, including the HRI and metallic layer, may further be embedded in, or covered by, one or more further layers of translucent or transparent material.

The term “translucent” or “translucency” as used within the present invention denotes the property of a material, typically of the substrate or the present film or sheet, to allow visible light (general wavelength range from ca. 400 to ca. 800 nm), e.g. solar light of the visible range, to pass through said material, with or without haze or scattering effects. The term “transparent” or “transparency” as used within the present invention denotes the property of a material to allow light of the visible range to pass through said material with a minimum of scattering effects. The terms generally mean translucency or transparency for electromagnetic waves from the visible range of solar light, permitting transmission of at least 30%, preferably at least 50%, and more preferably at least 85% of solar radiation energy of the visible range (especially 400 to 700 nm). Transparency or translucency implies that materials of the present film or sheet provide such property; in consequence, present substrate, passivation layer, antireflex coating, HRI layers and metal layer(s) are transparent or at least translucent in the visible range. Since metal layers loose transparency for visible light beyond a certain thickness, the metal layer is thin enough to ensure that a large fraction of visible light is able to pass through.

The term “window” as used within the present invention denotes a construction element, typically in a vehicle, in agriculture or especially in architecture, which is placed in a wall, or constitutes said wall, whereby the wall typically separates an interior room (typically an interior room of a vehicle or especially a building) from another interior room or especially an exterior room (typically the outdoor environment), in order to allow light to pass through the wall (typically sunlight passing from the exterior into the interior room).

The term “window pane” as used within the present invention denotes the translucent, especially transparent, construction element of the window consisting of translucent, especially transparent, material, typically the window without frame or fittings.

A typical example for a transparent window pane according to the invention is a building window, or vehicle window e.g. in a bus or train.

The term “metallic layer” as used within the present invention generally denotes an essentially isotropic layer providing metallic conductivity in both dimensions, the layer generally extending parallel to the substrate plane. The thickness of the metallic layer is low, such that translucency or transparency of the final film or sheet is provided.

The term “interrupted metallic layer” as used within the present invention denotes a metallic layer which is interrupted with a certain periodicity, essentially without metallic conductivity between 2 or more interrupted sections of said layer, while there is metallic conductivity within the non-interrupted stripes or sections of this layer. Interruption implies a spatial separation in at least one dimension, which may be effected by unmetallized sections within the layer plane (e.g. as shown in FIG. 7), and/or by sections of the metallic layer shifted out of the layer plane by a distance larger than the thickness of the metallic layer.

The term “thin” within “thin metallic layer” as used within the present invention thus denotes a thickness being, in direction perpendicular to the substrate plane, smaller than the interruptions within that metallic layer and/or smaller than the thickness of the layer of dielectric high refractive index material above or below it.

The term “periodicity” as used within the present invention, e.g. for interruptions of the metallic layer or patterns used for manufacturing the interrupted metallic layer, generally denotes the shortest width (mean value) of any spacing between 2 neighbouring sections of the metallic layer plus the width of one neighbouring section of the metallic layer; it is typically about the same as the periodicity of the periodicity of a grating, which may be used for introducing interruptions into the metallic layer (see further below; measured, for instance, as distance of 2 neighbouring peak centers of the grating, in direction perpendicular to the grating length).

The term “duty cycle” as used within the present invention denotes the ratio of the area covered by metal to the total area in any section of the film or sheet containing the layer structure as of present invention. In case of interruptions in the form of a line grating, the duty cycle equals the periodicity minus the width of one interruption, which difference is divided by the periodicity (i.e. the ratio DC/P as shown, for example, in FIG. 7).

The invention further pertains to an optical device comprising said characterizing features.

The substrate typically comprises a flat or bent polymer sheet or glass sheet, or polymer sheet and glass sheet. The metallic layer with HRI layer on the substrate typically is encapsulated by a suitable translucent, or preferably transparent, medium.

The devices of the invention, such as films, comprise metallic structures and may be combined with further known measures for light management and/or heat management, such as films. The devices or films may be designed to show colored or color neutral transmission properties. Devices of the invention, such as films, or glazings or solar panels equipped with films of the invention, have the additional advantage of cost effective production (processes including roll-to-roll hot embossing or UV replication and dielectric thin film coating processes).

Since the present devices provide for IR reflection without significant dependence on the irradiation angle, the final window pane, facade element or protection foil for the PV cell or solar panel may be installed in any position relative to the incoming sunlight.

The metal (of the interrupted metallic layer) basically may be selected from any substance showing metallic conductivity, and which is generally able to interact with light through a surface plasmon or polaron mechanism. Besides metals, semiconducting materials such as silicon (Si), indium tin oxid (ITO), indium oxide, Aluminum doped zinc oxide (AZO), Gallium doped zinc oxide (GZO) and similar materials thus may be used. The metal is preferably selected from the group noted above; especially preferred is silver.

The substrate as well as the passivation layer generally can be of any form or material as far as it is translucent, and especially transparent, to at least a part of solar electromagnetic radiation. The device of the invention comprises at least one substrate, which is preferably a dielectricum or an electrical isolator. The substrate may be of any material the person skilled in the art knows for providing such a translucent, or preferably transparent substrate. The substrate may be flexible or rigid. The substrate may comprise glass, e.g. containing metal compounds selected from the group consisting of metal oxides, metal sulfides, metal nitrides and ceramics or two or more thereof. The shape of the device may be in form of a sheet or film or foil, or at least parts of a foil. The extension of the device in two dimensions may range from some millimeters up to some meters or even kilometers, e.g. in the case of printing rolls. The extension in the third dimension is preferably between 10 nm and 10 mm, more preferably between 50 nm and 5 mm and most preferably between 100 nm and 5 mm. Beyond the substrate, the device may comprise further materials, like a polymer layer or a further layer. For example, the passivation layer may be a polymer layer. If the structure comprises at least one material beyond the substrate it is called a layered structure.

The invention thus further pertains to a method for reducing the transmission of solar light, for example to a method for reducing the transmission of IR radiation from the range 700 to 1200 nm, through a device or transparent element or window or PV cell cover such as noted above. The method of the invention comprises integrating the above device into a transparent element, which is typically a construction element. The transparent element may be an architectural element, a photovoltaic element, an element for agriculture or an element in a vehicle, it is especially preferred in the form and/or function of a PV cell or solar panel. Similarly, entry of visible light or ultraviolet light may be modified by the device of the invention noted above, where the term “modification” may stand for a desired change of color and/or increased reflection of those light frequencies, whose entry through the transparent element or window is undesired.

The substrate generally may have a thickness up to several millimeter, for example ranging from 1 micrometer (e.g. in the case of polymer films) up to 10 mm (eg in the case of polymer sheets or glass); in one preferred embodiment, the substrate is a polymer layer, or combination of polymer layers, whose thickness (together) ranges from 500 nm to about 300 micrometer.

For the usage in glazings, such as architectural windows, or vehicle windows, the substrate as well as the medium should be transparent at least in the visible region in the range from 300 to 800 nm, especially 400 to 700 nm. However materials commonly used for glazings, for example glass or plastics, often also transmit electromagnetic waves in a broader region up to 2500 nm, especially up to 1400 nm.

The substrate may comprise, or be built of, any material the person skilled in the art would use to provide the before mentioned usages. Examples for suitable materials and preferred preparation processes are given further below.

Additionally, the device may comprise one or more further layer(s), for example in the form of a further polymer layer. The further layer may differ in material and properties from the substrate and/or the medium. For example, the further layer may give the structure a more rigid constitution to protect especially the metallic and HRI layers from mechanical forces.

Interrupted metallic layers embedded in HRI material, as required in the device of the present invention, may be prepared by partial metallization of the structured surface by processes such as vapor deposition, sputtering, printing, casting or stamping. Full coverage of the surface by metal can be prevented, for example, by application of a shadow mask, photoresist techniques. In a preferred method, the metal structures are applied by directed deposition of the metal under an oblique angle onto a previously prepared grating structure, e.g. on a glass surface or on a resin surface, as explained further below.

### Manufacturing Methods

The preparation involves the step of providing the substrate comprising a surface. The substrate may be provided in form of a planar structure like a sheet, film, foil or layer or only parts thereof. The shape and dimension of the substrate may be chosen as required for its later application in/on a window pane, glass facade element, solar panel or solar cell. The advantageously planar structure may be flexible or rigid depending on the material it consists of.

According to one method, at least one of the surfaces of the substrate is then structured in a transforming step. In one embodiment of the invention, said transforming step is selected from the group consisting of embossing, stamping and printing. These processes are well known to the person skilled in the art. In a further step, the layers of HRI material and the interrupted metallic structures are attached onto the thus pre-structured substrate as explained below in detail.

In a preferred embodiment, the substrate comprises an organic polymer, typically selected from the group consisting of polymethyl methacrylate, polyethylene terephthalate, polyethylene, polycarbonate, polyetherimide, polyetherketone, polyethylene naphthalate, polyimide, polystyrene, poly-oxy-methylene, polypropylene, polyvinyl chloride, polyvinylbutyral or two or more thereof. The substrate may additionally comprise a further material, preferably any kind of hot embossable polymers or UV curable resins.

In another preferred embodiment, the substrate comprises a glass sheet, which is coated with an embossable coating comprising a hot embossable polymer, a UV curable resin or an inorganic sol-gel material.

In a more specific aspect, the invention relates to a process to provide a way to generate a device structure in the form as described before, the process for producing a device according to the present invention comprising the steps:
i. providing a transparent substrate exposing a surface,
ii. structuring the substrate to obtain a three-dimensional pattern (exposing nanoplanes, such as by a grating) having a periodicity ranging from 50 to 800 nm, and preferably a depth (measured rectangular to the substrate plane) from the range 5 to 100 nm,
iii. depositing a layer of high refractive index material onto at least one structured surface thus obtained
iv. depositing a metal on a part of the thus structured surface, preferably by vapor deposition or sputtering, under an oblique angle,
v. depositing a layer of high refractive index material onto the metallic layer thus obtained, and
vi. covering the layer of high refractive index material obtained in step (v) with one or more layers of a translucent or transparent dielectric material.

Suitable methods for patterning metallic layers and thus forming interrupted metallic structures are generally known in the art. Preferred is a method wherein a grating on the substrate is obtained by an embossing step, e.g. as described in EP-A-1767964, WO2009/068462, WO2012/147052, U.S. Pat. No. 4,913,858, U.S. Pat. No. 4,728,377, U.S. Pat. No. 5,549,774, WO2008/061930 or Gale et al., Optics and Lasers in Engineering 43, 373 (2005), as well as literature cited therein; the preparation of suitable embossing tools, such as grating masters, is explained, inter alia, in WO2012/147052, WO2009/062867, US-2005-239935, WO 95/22448; a preferred method is given by Zaidi et al., Appl. Optics 27, 2999 (1988), describing the preparation of nearly rectangular shaped photoresist gratings using standard holographic two beam interference set-up.

Other useful structuring methods to obtain the grating such as holographic patterning, dry etching etc. are described, for example, in US-2005-153464, WO2008/128365.

In a typical fabrication process, interference lithography is used to pattern a photoresist on top of a quartz or silicon substrate. The photoresist is developed and the pattern is transferred to the substrate by etching. A grating with controlled shape, depth and duty cycle is obtained.

The result of the development step may be a continuous surface relief structure, holding, for example, a sinusoidal or rectangular cross section or a cross section of a combination of several sinusoidal and/or rectangular cross sections of the obtained grating. Resists that are exposed to electron beams or plasma etching typically result in binary surface structures, typical for a rectangular form of the cross-section. Continuous and binary surface relief structures result in very similar optical behaviors. By a galvanic step the typically soft resist material then may be converted into a hard and robust metal surface, for example into a Nickel shim. This metal surface may be employed as an embossing tool.

The quartz or silicon grating, or preferably the Ni-shim, is then used as a master for replication onto the final substrate, for example a UV cured polymer material. Alternatively, replication can be effected by hot embossing at a temperature preferably above the substrate's glass transition temperature; this technique is especially effective on substrates like PET, PMMA and especially PC. With this embossing tool providing the master surface, a medium in form of a polymer layer or foil can be embossed.

The grating structures may also be transferred directly onto a glass surface. Possible transfer techniques are based on reactive ion etching or the use of replicated inorganic sol-gel materials.

The grating of the substrate (and hence the typical periodicity of interruptions of the metallic layer) is preferably of a periodicity from the range 50 to 800 nm, more preferably 100 to 500 nm. The grating depth and width is selected to provide the desired duty cycle after metallization under an oblique angle; typically, the depth may range from 5 to 100 nm, especially 5 to 50 nm, while the width is within the range from about 1 to about 10 percent of the periodicity (measured from peak top through the cross section to the deepest level of the trench). The cross section of the grating peaks may be of various forms, e.g. in the form of waves, such as sinusoidal, or angled, for example trapezoidal, triangular or preferably rectangular (e.g. square, with aspect ratio roughly being 1:1), thus resulting in edges extending over the length of the grating. The aspect ratio (cross-sectional width:depth) is generally from the range 1:10 to 10:1, preferably from the range 1:5 to 5:1 (a ratio of about 1 standing for a typical square cross section of the grating peak).

The device of the invention typically is based on a rectangular or trapezoidal grating.

This deposition of the HRI material may be accomplished by processes known in the art, for example vacuum vapor deposition, sputtering, printing, casting or stamping or a combination of at least two of theses processes. Preferably, the HRI material is deposited by vacuum vapor deposition because this process has a high accuracy concerning the thickness of the deposited materials.

The thin, interrupted layer of metal may be provided by depositing the metal onto the substrate with HRI layer. Interrupted metallic structures, as required in the device of the present invention, typically are prepared by partial metallization of the surface by processes such as vapor deposition, sputtering, printing, casting or stamping. Full coverage of the surface by metal can be prevented, for example, by application of a shadow mask, photoresist techniques. In a preferred method, the metal structures are applied by directed deposition of the metal under an oblique angle onto a previously prepared grating structure, e.g. using a structured a resin surface below the 1st HRI layer. This is typically achieved by exposure of the grated surface to metal vapor under an oblique angle (e.g. 30-60°) with respect to the plane of the substrate. The deposition is typically effected on top, and on one or two sides of the grating.

The metal layer may also deposited vertically, e.g. onto a flat surface, with subsequent removal of parts the metal layer, e.g. on top of a previous grating, to obtain the necessary interruptions. Another way of preparing interrupted metal layers is deposition onto a surface which previously had been pre-structured, e.g. with a grating, where the depth of the pre-structures exceeds the thickness of the metal layer, thus resulting in a metal layer deposited on 2 or more levels of the previous HRI layer, which levels are not connected by metallic material (typically, such levels are interrupted by walls which are perpendicular or nearly perpendicular to the substrate plane); this method avoids the necessity of removing parts of the metal layer, or depositing the metal under an oblique angle.

This deposition steps may be established for example by vacuum vapor deposition, sputtering, printing, casting or stamping or a combination of at least two of theses processes. Preferably, the metal is deposited by vacuum vapor deposition because this process has a high accuracy concerning the thickness of the deposited materials.

The surface quality of the layers or films may be checked by tapping mode atomic force microscopy (AFM), Dimension 3100 close loop (Digital instrument Veeco metrology group). Both height and phase images are obtained during the scanning of samples. In general, the height image reflects the topographic change across the sample surface while the phase image reflects the stiffness variation of the materials. The mean roughness Ra represents the arithmetic average of the deviation from the center plane:

$${R}_{a} = \frac{{\sum }_{i = 1}^{N} \vert {Z}_{i} - {Z}_{cp} \vert}{N}$$

Here, Zcp is the Z value of the center plane.

The periodicity of the interrupts in the metallic structure (e.g. metallic layer) may generally be determined by the period of an underlying grating (P), typically from the range 50-800 nm.

The fabrication of a device of the invention typically may follow the steps shown in FIG. 8. It includes the following steps:

a) Provision of a substrate with a suitable grating structure as described, e.g. by hot- or UV-embossing (period typically from 50 to 800 nm, e.g. period 240 nm; depth typically from the range 5 to 100 nm, e.g. 8 to 30 nm; duty cycle (DC) from the range 0.7 to 0.99, e.g. 0.9); the hot-embossing may be carried out using a thermoplastic polymer foil such as a polyester (e.g. polyethyleneterephthalate (PET), polycarbonate (PC), poly-acrylmethacrylate (PMMA), or polyvinylbutyral film), or using a hot-embossible coating on the substrate;

the UV-embossing may be carried out using a UV-crosslinkable material (e.g. Lumogen® OVD 301).
b) A thin layer of high index of refraction material is then coated onto the patterned substrate (typically perpendicular onto the substrate, e.g. a ZnS layer of 30-40 nm thickness by PVD).
c) A thin layer of metal is coated onto the pre-structured substrate thus obtained (e.g. 5-15 nm by directed parallel material transport such as thermal evaporation or PVS; optionally obliquely under an angle from the range 10°-70° relative to the surface normal, especially where grating depth is same or smaller than metal layer thickness).
d) Another thin layer of high index of refraction material as of step (b) is coated onto the substrate coated according to the previous steps.
e) The patterned and coated substrate is passivated with a dielectric material such as a UV-cross-linkable coating (see below).
f) Optionally, an AR film is deposited on top of the patterned, coated and passivated device.

According to an alternative method, the film or sheet of the invention may be obtained by depositing a continuos metal layer, with introduction of interruptions into said metal layer in a separate manufacturing step:

Thus, the method for manufacturing a translucent or transparent film or sheet according to the invention may comprise the following steps:

g) providing a suitable film or sheet substrate (1);
h) depositing a layer of high refractive index material onto at least one surface of said substrate;
i) depositing a thin metallic layer onto the surface obtained in step (h);
j) introducing interruptions into the metallic layer by removal of 1 to 30% of the metallic layer area with a periodicity from the range 50 to 800 nm while retaining 70 to 99% of the metallic layer area essentially unmodified, for example by plasma etching, embossing, cutting or punching;
k) depositing another layer of high refractive index material onto said interrupted metallic layer of step (j);
l) covering the layer of high refractive index material obtained in step (k) with one or more layers of a translucent or transparent dielectric material; and optionally
m) depositing an antireflex layer onto the surface obtained in step (l).

The device of the invention advantageously has a high duty cycle (i.e. ratio of the area covered by metal to the total area) ranging from 0.7-0.99, preferably from about 0.8 to about 0.95 (corresponding to 80-95% of the area covered by metal).

The roughness Ra of the metallic layer typically is below 5 nm.

UV cured polymer materials, films as well as grating structures as obtained after replication, typically have a thickness of 1-100 micrometer, especially 3-20 micrometer. The material of the substrate and, independently, the passivation layer may, for example, be selected form the group consisting of a polymer, a glass, a ceramic, or two or more thereof. In a preferred embodiment the material is a thermoplastic polymer, e.g. a hot embossable mono- or multilayer thermoplastic film comprising an embossable surface of a material with glass transition temperature below 180° C., especially below 150° C.

In another preferred embodiment the substrate is glass, which is coated with an embossable layer such as a hot embossable thermoplastic layer or a curable coating such as a radiation curable coating composition.

The passivation layer is preferably a curable coating such as a radiation curable coating.

The polymer layers typically may have a thickness from the range of 100 nm to 1 mm, preferably from the range from 500 nm to 0.5 mm, the curable coating layer has preferably a dry film thickness from the range 800 nm to 200 μm.

In a preferred embodiment, the substrate and/or the passivation layer comprises at least one thermoplastic polymer. The substrate preferably comprises a hot embossable polymer or a UV curable resin.

The substrate as well as the passivation layer materials are typically selected from glass, polymers such as acrylates (typically polymethylmethacrylate, PMMA), polyethylen terephthalate (PET), polycarbonate (PC), polyvinylbutyrate (PVB), low refractive index composite materials or hybrid polymers such as Ormocer®, and sheets or films thereof, e.g. holographic films, such as acrylate-coated PET, radiation-curable compositions.

The substrate and/or the passivation layer preferably comprises a polymer selected from the group consisting of polymethyl methacrylate, polyethylene terephthalate, polyethylene, polycarbonate, polyetherimide, polyetherketone, polyethylene naphthalate, polyimide, polystyrene, poly-oxy-methylene, polypropylene, poly vinyl chloride, polyvinylbutyral, radiation curable compositions such as UV curable compositions, or two or more thereof.

The radiation cured polymer material, typically a polymer film, is prepared by irradiation of a radiation-curable composition, preferably during or directly after the embossing step, with the appropriate radiation such as UV light or electron beam.

Radiation-curable compositions generally are based on (and consist essentially of) oligomers and/or polymers, which comprise moieties capable to undergo crosslinking reactions upon irradiation e.g. with UV light. These compositions thus include UV-curable systems based on oligomeric urethane acrylates and/or acrylated acrylates, if desired in combination with other oligomers or monomers; and dual cure systems, which are cured first by heat or drying and subsequently by UV or electron irradiation, or vice versa, and whose components contain ethylenic double bonds capable to react on irradiation with UV light in presence of a photoinitiator or with an electron beam. Radiation-curable coating compositions generally are based on a binder comprising monomeric and/or oligomeric compounds containing ethylenically unsaturated bonds (prepolymers), which, after application, are cured by actinic radiation, i.e. converted into a crosslinked, high molecular weight form. Where the system is UV-curing, it often contains a photoinitiator as well. Corresponding systems are described e.g. in Ullmann's Encyclopedia of Industrial Chemistry, 5th Edition, Vol. A18, pages 451 453.

Examples are UV-curable resin systems of the Lumogen series (BASF), such as Lumogen® OVD 301. The radiation curable composition may, for example, comprise an epoxy-acrylate from the CRAYNOR® Sartomer Europe range (10 to 60%) and one or several acrylates (monofunctional and multifunctional), monomers which are available from Sartomer Europe (20 to 90%) and one, or several photoinitiators (1 to 15%) such as Darocure® 1173 and a levelling agent such as BYK®361 (0.01 to 1%) from BYK Chemie.

The substrate comprising the device as finally obtained, and typically the window pane or the photovoltaic module comprising the device, may be flat or bent; curved shapes (as, for example, for automobile front screens or rear screens) are typically introduced in a molding process after production of the device of the invention.

The present invention thus includes, but is not limited to, the following embodiments:

### Embodiment A

A translucent or transparent film or sheet comprising a substrate (1) covered with a layer of a dielectric high refractive index material (4) containing a thin metallic layer (3) embedded in said material, and a further layer (5) of translucent or transparent material covering said layer (4) of dielectric high refractive index material, characterized in that the refractive index of the high refractive index material is higher than 1.9, the thickness of the metal layer (3), perpendicular to the substrate plane, is from the range 4 to 20 nm, said translucent or transparent material permits transmission of at least 30% of solar radiation energy of the visible range, and the embedded metal layer (3) is periodically interrupted with a periodicity of 50 to 800 nm such that metal covers at least 70% of the substrate area.

### Embodiment B

Film or sheet according to any of embodiments A or C to N, wherein the refractive index of the high refractive index material is from the range 2.0 to 2.8.

### Embodiment C

Film or sheet according to any of embodiments A, B or D to N, wherein the periodicity of interruptions in the metal layer (3) within at least one dimension is from the range 100 to 500 nm.

### Embodiment D

Film or sheet according to any of embodiments A to C or F to N, wherein the embedded metal layer covers 70 to 99%, especially 80 to 95%, of the substrate area.

### Embodiment E

Film or sheet of embodiment C, wherein the embedded metal layer covers 70 to 99%, especially 80 to 95%, of the substrate area.

### Embodiment F

Film or sheet according to any of embodiments A to E or G to N, wherein the thickness of the metal layer (3), perpendicular to the substrate plane, is from the range 5 to 15 nm.

### Embodiment G

Film or sheet according to any of embodiments A to F or H to N, wherein the thickness of the layer of dielectric high refractive index material (4) is 20 to 50 nm, especially 30-40 nm, on each side of the metal layer.

### Embodiment H

Film or sheet according to any of embodiments A to G or I to N, wherein the metal layer essentially consists of silver, aluminum, copper, gold, especially silver.

### Embodiment I

Film or sheet according to any of embodiments A to H or J to N, wherein the high refractive index material is selected from metal chalcogenides and metal nitrides, preferably of the metals Al, In, Ga, Si, Sn, Ce, Hf, Nb, Ta, Zn, Ti, Zr and binary alkaline chalcogenides and nitrides of these metals, especially oxides, alkoxides, nitrides, sulphides such as zinc sulphide.

### Embodiment J

Film or sheet according to any of embodiments A to I or K to N, wherein the further layer (5) is a passivation layer.

### Embodiment K

Film or sheet according to any of embodiments A to J or L to N, which additionally comprises an antireflex coating (2) on top of the further layer (5).

### Embodiment L

Film or sheet according to any of embodiments A to J or N, wherein adjacent layers (1), (3), (4), (5) each are in direct optical contact with each other.

### Embodiment M

Film or sheet according to embodiment K, wherein adjacent layers (1), (3), (4), (5) and (2) each are in direct optical contact with each other.

### Embodiment N

Film or sheet according to any of embodiments A to M, wherein the substrate (1) and/or the further layer (5) are polymeric materials or glass, e.g. selected from thermoplastic polymers and UV-cured polymers such as acrylic polymers, polycarbonates, polyesters, polyvinylbutyrate, polyolefines, polyetherimides, polyetherketones, polyethylene naphthalates, polyimides, polystyrenes, polyoxymethylene, polyvinylchloride, low refractive index composite materials or hybrid polymers, radiation-curable compositions, or two or more thereof.

### Embodiment O

Window, glass facade element or solar panel comprising the film or sheet according to any of embodiments A to N.

### Embodiment P

Solar panel of embodiment O containing the film or sheet according to any of embodiments A to N positioned as a cover film of photovoltaic cells comprised in said solar panel.

### Embodiment Q

Method for manufacturing a translucent or transparent film or sheet according to any of embodiments A to N, which method comprises the steps

a) structuring at least one surface of a suitable film or sheet substrate (1) to obtain grooves or ditches with a periodicity from the range 50 to 800 nm and a suitable width and depth, typically a width of about 4 to about 10 percent of the periodic, and a depth typically from the range 5 to 100 nm;
b) depositing a layer of high refractive index material onto at least one structured surface thus obtained;
c) depositing a thin metallic layer by thermal evaporation or physical vapor deposition, optionally under an oblique angle, onto the surface obtained in step (b), thus obtaining interruptions in the metallic layer which are at least partially located at the grooves or ditches introduced in step (a);
d) depositing another layer of high refractive index material onto said interrupted metallic layer of step (c);
e) covering the layer of high refractive index material obtained in step (d) with one or more layers of a translucent or transparent dielectric material; and optionally
f) depositing an antireflex layer onto the surface obtained in step (e).

### Embodiment R

Method for manufacturing a translucent or transparent film or sheet according to any of embodiments A to N, which method comprises

g) providing a suitable film or sheet substrate (1);
h) depositing a layer of high refractive index material onto at least one surface of said substrate;
i) depositing a thin metallic layer onto the surface obtained in step (h);
j) introducing interruptions into the metallic layer by removal of 1 to 30% of the metallic layer area with a periodicity from the range 50 to 800 nm while retaining 70 to 99% of the metallic layer area essentially unmodified, for example by plasma etching, embossing, cutting or punching;
k) depositing another layer of high refractive index material onto said interrupted metallic layer of step (j);
l) covering the layer of high refractive index material obtained in step (k) with one or more layers of a translucent or transparent dielectric material; and optionally
m) depositing an antireflex layer onto the surface obtained in step (l).

### Embodiment S

Window pane, glass facade element or solar panel of embodiment O or P, wherein the substrate comprises a flat or bent polymer film or sheet, or glass sheet, or a polymer film or sheet and a glass sheet.

### Embodiment T

Method for reducing the transmission of solar IR radiation from the range 700 to 1200 nm, through a transparent element such as a polymer film, plastic screen, plastic sheet, plastic plate, glass screen, especially of a window, architectural glass element or solar panel, which method comprises integrating film or sheet according to any of embodiments A to N into said transparent element, especially a transparent element covering solar cells.

### Embodiment U

Use of a film or sheet according to any of embodiments A to N for reducing entry of IR radiation through a window or glass facade element into the interior space of a building, or for reducing heat uptake of a solar panel or photovoltaic cell.

The following examples illustrate the invention. Wherever noted, room temperature (r.t.) depicts a temperature from the range 22-25° C.; over night means a period of 12 to 15 hours; percentages are given by weight, if not indicated otherwise. Absolute values specified for refractive indices are as determined at 589 nm (sodium D line), if not indicated otherwise. ISO 9050 has been applied in the second edition 15. August 2003. DIN EN 410 has been applied in the edition of April 2011. Gratings are of square cross sections unless indicated otherwise.

### ABBREVIATIONS

AR antireflex
DC duty cycle (i.e. ratio of the area covered by metal to the total area)
PMMA polymethylmethacrylate
PVD physical vapor deposition
R IR reflection (1.95 micrometer radiation)T_{VIS}, τᵥ Visible solar energy transmittance (ISO 9050, DIN EN 410)

### SEM Scanning Electron Microscopy

### EXAMPLES

### Example 1: Protection Foil Containing Silver on ZnS Grating

The following materials are chosen:

| | |
|---|---|
| metal | silver |
| high index refraction material | ZnS |
| substrate | PMMA film, thickness 125 micrometer |
| passivation layer | UV cured Lumogen ® OVD 301 |

single layer antireflex (AR) coating low refractive index SiO2 nanoparticle coating The AR coating is as described by Wicht et al., Macromolecular Materials and Engineering 295, 628 (2010), using 1.3 g of SiO2 nanoparticles of 8 nm primary particle size and 0.3 g of polyvinyl alcohol on 35 ml water and 0.01 g of sodium tetraborate.

The geometry of the AR and the metal/high index of refraction layers are;

| | |
|---|---|
| AR layer thickness | 115 nm |
| refractive index of AR layer | 1.22 |
| silver layer thickness | 9 nm (horizontal and vertical part) |
| silver grating period | 240 nm |
| duty cycle (DC) | 0.9 |
| ZnS thickness | 35 nm each (underneath and |
| | above silver layer) |
| passivation layer thickness | 5 μm |

The thickness of the passivation layer is typically from the range 5 μm or more, thus having no significant impact on the optical properties of the protection foil. The profile of the resulting protective foil is shown in FIG. 1.

The device shown in FIG. 1 is obtained as shown in FIG. 8:

i) a 125 micrometer PMMA film is hot embossed (line grating of period 240 nm, depth 9 nm, trench width 24 nm);
ii) a thin layer of zinc sulphide (ZnS 35 nm) is coated onto the patterned substrate (Baizers BAE 250, coating perpendicular to the substrate);
iii) the patterned ZnS layer thus obtained is then coated on the top areas and one side area of the grating with a silver layer using physical vapour deposition of silver from the side using a thermal evaporator vacuum chamber. The silver thickness selected is 9 nm on top and side, evaporation angle is 50°, such that only a part of the grating is metalized;
iv) another layer of ZnS (35 nm, Balzers BAF 250) is deposited, also filling the trenches not coated in step iii), thus isolating the silver coated areas from each other;
v) the patterned and coated substrate thus obtained is passivated with Lumogen® OVD 301 abd UV cured (dry film thickness 5 micrometer); and
vi) an AR film of composition described above is coated onto the passivation layer.

Based on the above material and geometrical data, the transmission and reflection of the protective optical foil is simulated under the assumption, that the substrate is semi-infinite such that no reflections occur at the lower substrate interface (opposite to the AR layer). The transmission and reflection for perpendicular incident light (θ=0°) is shown in FIG. 2. The transmission and reflection for an incident light (θ=60°) is shown in FIG. 3. The plane of incident light is perpendicular to the grating orientation.

From the simulated photo-spectra, the light transmittance τᵥ according to the European standard DIN EN 410 or (equivalently) the international standard ISO 9050, and reflection R (at 1.95 micrometer, i.e. the approx. maximum of the infrared reflection) are extracted and summarized in Table 1.

TABLE 1
extracted transmittance τᵥ and reflection in the infrared
from the simulated transmission and reflection spectra

| incidence angle θ | τᵥ | R(1.95 μm) |
|---|---|---|
| 0° | 96% | 83% |
| 60° | 90% | 80% |

From FIG. 2, FIG. 3 and Table 1 it is seen that the metallic grating with the ZnS layers and the AR coating on top of the protection foil results in a high visible transmittance τᵥ(0°) of 96% and a maximal reflection of 83% at 1.95 μm in the infrared, while showing a weak angular dependence.

### Example 2 (Comparison): Non Patterned (Continuous) Silver Layer

For the purpose of comparison, a simulation as described in example 1 is also carried out for a protective device with a non-patterned thin silver layer. The cross-section of the device is shown in FIG. 4; silver thickness of 9 nm, each ZnS layer of thickness of 35 nm, substrate, passivation layer and AR layer are as in example 1. The transmission and reflection spectra are shown in FIG. 5 (θ=0°) and FIG. 6 (θ=60°). From the simulated photo-spectra, the transmittance and reflection R (at 1.95 micrometer, i.e. the approx. maximum of the infrared reflection) in the infrared are extracted and summarized in Table 2.

TABLE 2
extracted transmittance τᵥ and reflection in the infrared
from the simulated transmission and reflection spectra for
the device with the non-patterned silver layer

| incidence angle θ | τᵥ | R(1.95 μm) |
|---|---|---|
| 0° | 98% | 72% |
| 60° | 94% | 70% |

The protective foil based on the non-patterned silver film shows a slightly higher transmittance (difference: 2% at 0° and 4% at 60°) and a distinctly lower infrared reflection (difference: 11% at 0° and 10% at 60°) compared to the same device comprising the interrupted silver layer according to the present invention.

### Example 3: Protection Foil Containing Interrupted Flat Silver Layer Embedded in ZnS Layer

An additional example of a protective foil based on a patterned metal is shown in FIG. 7.

### Example 4

FIG. 9 shows a further approach to fabricate the described optical device. Instead of embossing wells (FIG. 8), elevations are embossed. The first HRI coating (FIG. 9 b) may be preferable over the approach illustrated by FIG. 8 (b). Again, interruptions in the metallic layer are obtained as an effect of the grating shadow during metallization under oblique angle.

### Example 5: Fabrication of a Device by Perpendicular Coatings and Nano-Cutting

In the method shown in FIG. 10, interruptions in the metallic layer are obtained by cutting. The substrate is subsequently coated with the HRI material and the metal layer. Then, the metal layer and, in part, the underlying HRI layer is cut using a nano-cutting tool. Finally the device is coated with another layer of HRI material and a passivation material.

The step of nano-cutting is carried out in analogy to the method described by N. Stutzmann et. al., Advanced Functional Materials 12, 105 (2003).

An optical simulation of the device based on the patterned layers shown in FIG. 10 is carried out using the following parameters:

| | |
|---|---|
| period | 240 nm |
| silver thickness | 9 nm |
| duty cycle | 0.95 |
| HRI material | ZnS |
| thickness ZnS (each layer) | 35 nm |
| substrate, superstrate | PMMA |
| thicknesses substrate, superstrate | semi-infinite |
| light of incidence angle | 0° (perpendicular to device) |

The simulated transmission and reflection spectra are shown in FIG. 12. The resulting τᵥ=97% and the reflection R(1.95 μm)=82%.

### Example 6: Fabrication of a Device by Nano-Embossing and by Perpendicular Coatings

FIG. 11 shows a further approach to fabricate described optical devices. Here again, trenches are embossed and the HRI material is coated perpendicular to the substrate. In the next steps, a metal and a second HRI layer are subsequently coated perpendicular to the substrate. Finally the device is passivated with a UV cross-linkable material.

In this approach, the metal layer is interrupted at two locations per period and results in two metal layers a major raised metal area and a minor lowered metal area. The metal coverage (duty cycle) is defined by the ratio of the major metal area to the total area, the metal layer (major and minor) thus covers the total coated area, the duty cycle thus being 100%.

After the device fabrication, an antireflective coating for the visible wavelength range is advantageously applied to the top of the device.

Optical simulations of the device based on the patterned layers shown in FIG. 11 are carried out using the following parameters:

| | |
|---|---|
| grating period | 240 nm |
| grating depth | 26 nm (distance |
| | between major and |
| | minor metal areas) |
| silver thickness | 9 nm |
| fraction of elevated metal layer (DC') | 0.95 |
| HRI material | ZnS |
| thickness ZnS | 35 nm |
| substrate, superstrate | PMMA |
| thicknesses substrate, superstrate | semi-infinite |
| light of incidence angle | 0° (perpendicular to device) |

The simulated transmission and reflection spectra are shown in FIG. 13. The resulting τᵥ=97% and the reflection R(1.95 μm)=81%.

### BRIEF DESCRIPTION OF FIGURES

FIG. 1 Cross-section through the protective foil, which contains
1: foil substrate
2: AR coating
3: patterned metal layer (thickness d; duty cycle=DC/P)
4: high index of refraction layer above and underneath the metal layer
5: passivation or spacer layer between the upper high index of refraction layer and the AR coating.

FIG. 2 Simulated transmission and reflection spectra for θ=0°.

FIG. 3 Simulated transmission and reflection spectra for θ=60°.

FIG. 4 Cross-section through the protective foil based on an non-patterned metal layer, which contains
1: foil substrate
2: AR coating
3: thin metal layer of thickness d
4: high index of refraction layer above and underneath the metal layer
5: passivation or spacer layer between the upper high index of refraction layer and the AR coating.

FIG. 5 Simulated transmission and reflection spectra for θ=0° for the non-patterned metal layer.

FIG. 6 Simulated transmission and reflection spectra for θ=60° for the non-patterned metal layer.

FIG. 7 Cross-section through the additional protective foil based on a patterned metal layer, parameter as defined in FIG. 1.

FIG. 8 Fabrication of a device as shown in FIG. 1; a) substrate is hot- or UV-embossed, b) a thin layer of HRI material is coated onto the patterned substrate (coating perpendicular to the substrate); c) a thin layer of metal is coated obliquely; d) a thin layer of HRI material is coated onto the patterned substrate (coating perpendicular to the substrate); e) the patterned and coated substrate is passivated with a dielectric material; f) antireflex film on top of the patterned, coated and passivated foil.

FIG. 9 Alternative fabrication of a device: a) substrate is hot- or UV-embossed, b) a thin layer of HRI material is coated onto the patterned substrate (coating perpendicular to the substrate); c) a thin layer of metal is coated obliquely; d) a thin layer of HRI material is coated onto the patterned substrate (coating perpendicular to the substrate); e) the patterned and coated substrate is passivated with a dielectric material.

FIG. 10 Fabrication of a device by nano-cutting: a) the substrate is coated with a layer of HRI material; b) a thin layer of metal is coated onto the HRI layer (coating typically perpendicular to the substrate, no oblique angle required); c) with a cutting tool holding the required period, the coated substrate is embossed such that the metal layer gets patterned with thin slits d) a thin layer of HRI material is coated onto the patterned substrate (coating perpendicular to the substrate); e) the patterned and coated substrate is passivated with a dielectric material.

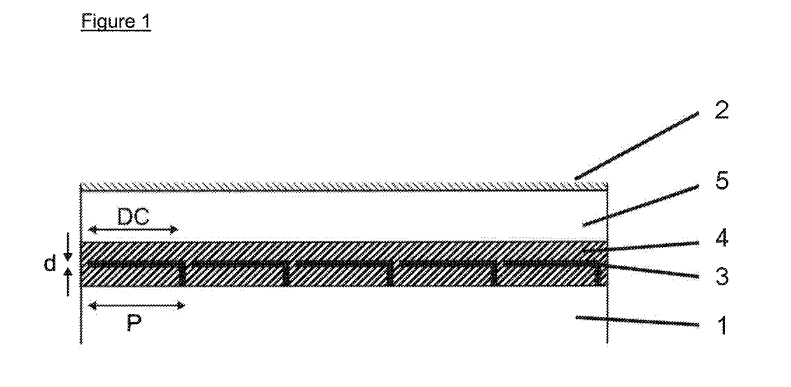

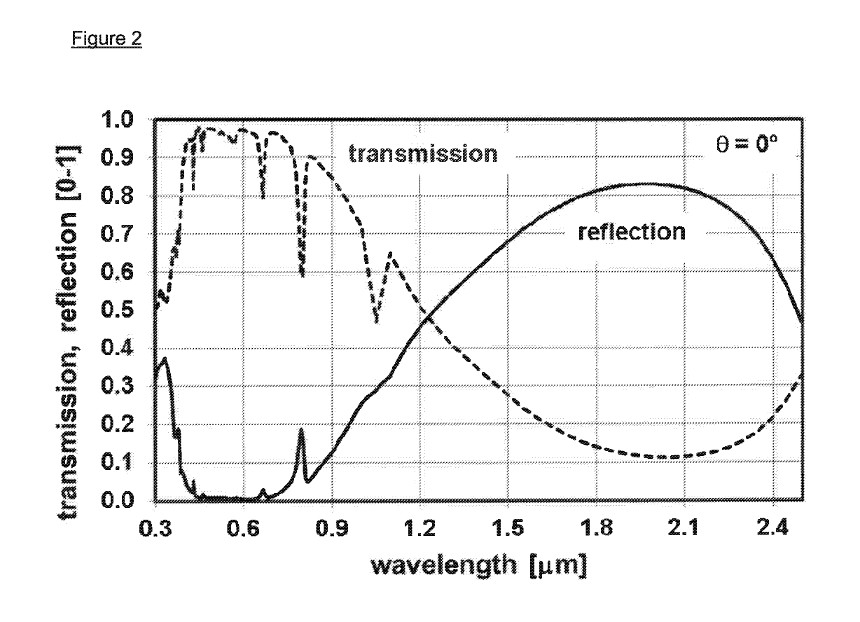

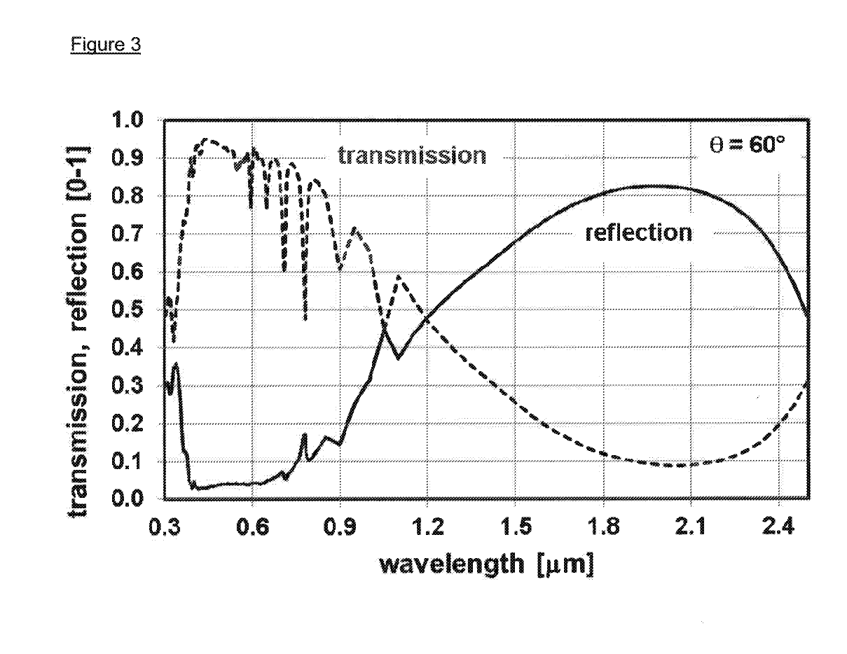

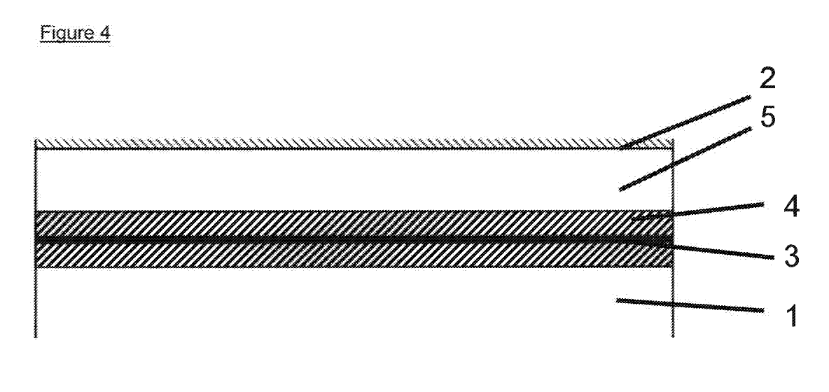

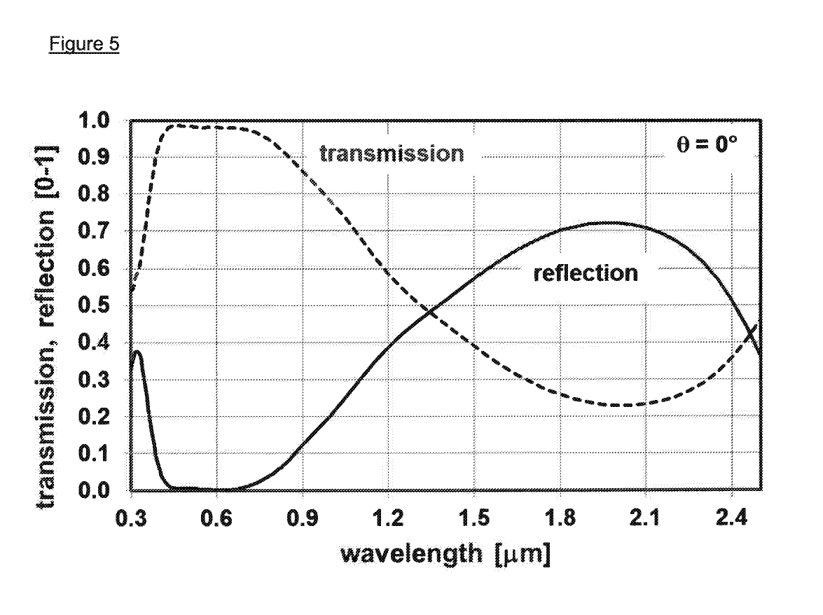

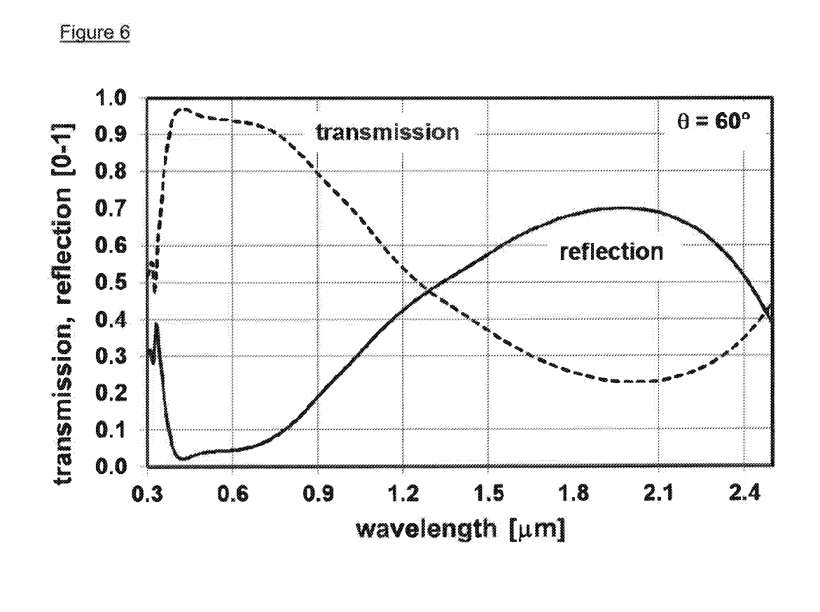

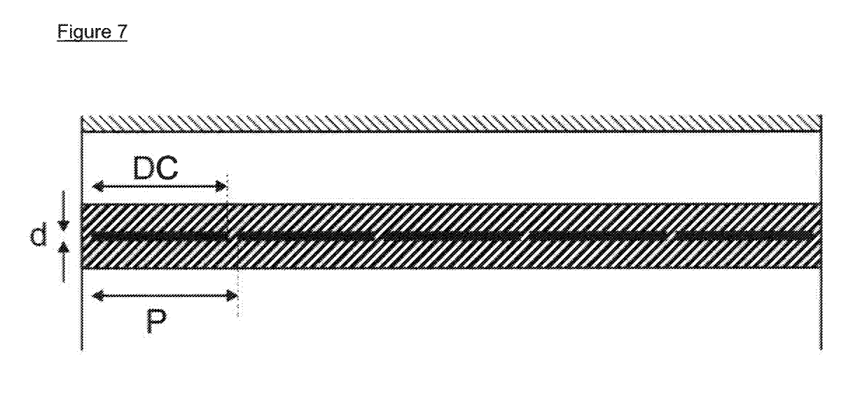

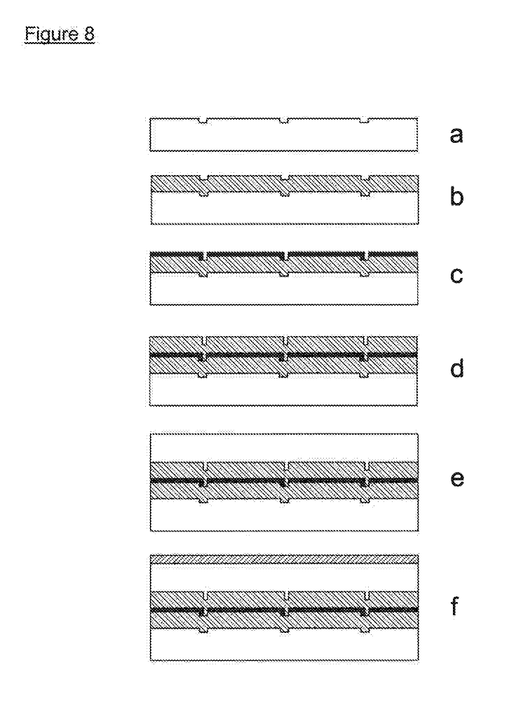

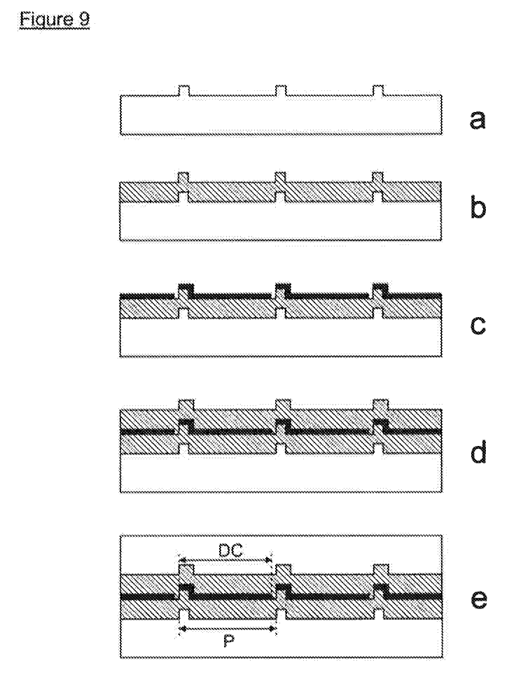

FIG. 11 Fabrication of a device by embossing followed by conventional PVD:
a) the substrate is hot- or UV-embossed, depth typically larger than intended thickness of metal layer, and less than intended thickness of HRI layer;
b) the thin layer of HRI material is coated onto the patterned substrate (coating perpendicular to the substrate);
c) the thin layer of metal is coated perpendicular to the substrate;
d) the 2nd thin layer of HRI material is coated onto the patterned substrate (coating perpendicular to the substrate);
e) the patterned and coated substrate is passivated with dielectric material.

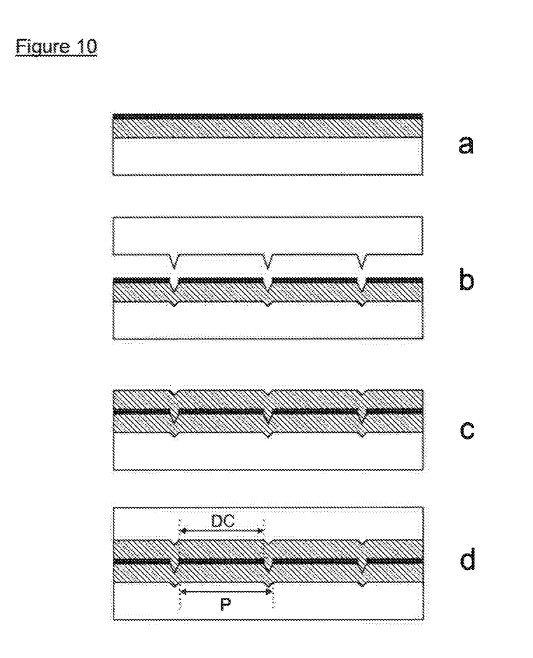

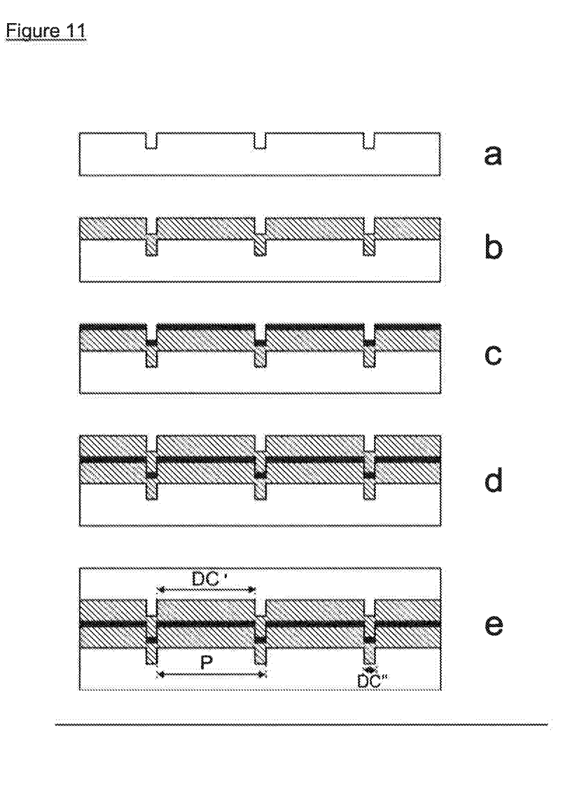

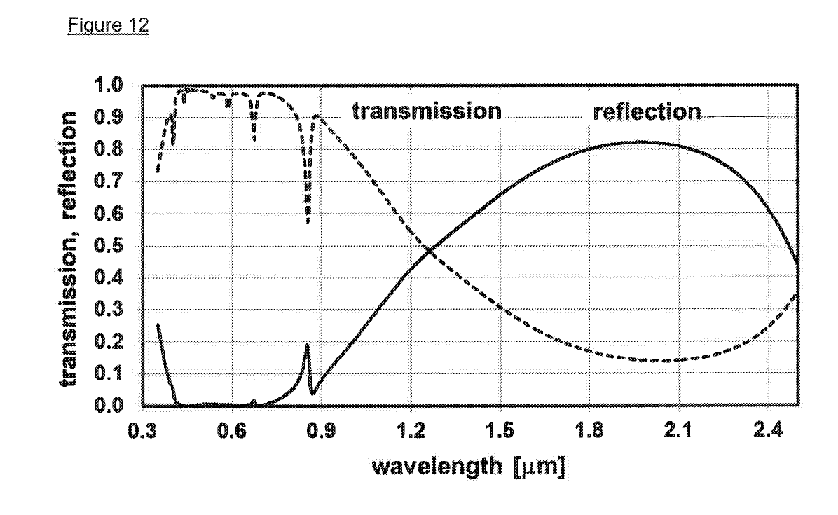

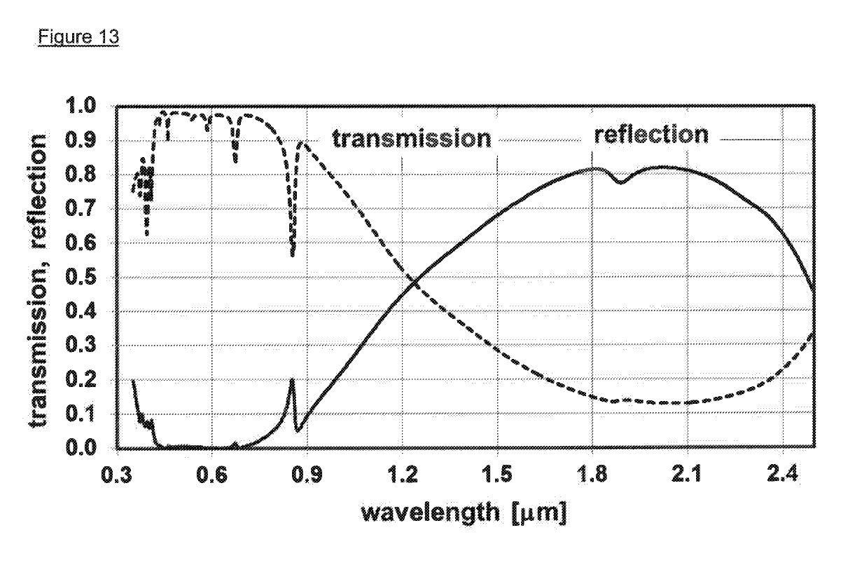

FIG. 12 Simulated transmission and reflection spectra based on patterned layers as shown in FIG. 10.

FIG. 13 Simulated transmission and reflection spectra based on patterned layers as shown in FIG. 11.

1.-16. (canceled)

17. A translucent or transparent film or sheet comprising a substrate (1) covered with a layer of a dielectric high refractive index material (4) containing a thin metallic layer (3) embedded in said material, and a further layer (5) of translucent or transparent material covering said layer (4) of dielectric high refractive index material, characterized in that the embedded metal layer (3) is periodically interrupted with a periodicity of 50 to 800 nm such that metal covers at least 70% of the substrate area.

18. The film or sheet of claim 17, wherein the refractive index of the high refractive index material is higher than 1.9.

19. The film or sheet of claim 17, wherein the periodicity of interruptions in the metal layer (3) within at least one dimension is from the range 100 to 500 nm, or the embedded metal layer covers 70 to 99% of the substrate area.

20. The film or sheet according to claim 17, wherein the thickness of the metal layer (3), perpendicular to the substrate plane, is from the range 4 to 20 nm, or the thickness of the layer of dielectric high refractive index material (4) is 20 to 50 nm on each side of the metal layer.

21. The film or sheet according to claim 17, wherein the metal layer consists essentially of silver, aluminum, copper, or gold.

22. The film or sheet according to claim 17, wherein the high refractive index material is selected from the group consisting of metal chalcogenides and metal nitrides.

23. The film or sheet according to claim 17, further comprising an antireflex coating (2) on top of the further layer (5).

24. The film or sheet according to claim 23, wherein adjacent layers (1), (3), (4), (5) and optionally (2) each are in direct optical contact with each other.

25. A window, glass facade element or solar panel comprising the film or sheet according to claim 17.

26. The window, glass facade element, or solar panel claim 25, wherein the window, glass façade element, or solar panel is a solar panel, and wherein the film or sheet is positioned as a cover film of photovoltaic cells comprised in said solar panel.

27. A method for manufacturing the translucent or transparent film or sheet according to claim 17, which method comprises
a) structuring at least one surface of a suitable film or sheet substrate (1) to obtain grooves or ditches with a periodicity from the range 50 to 800 nm and a width of about 4 to about 10 percent of the periodic, and a depth from the range 5 to 100 nm;
b) depositing a layer of high refractive index material onto at least one structured surface thus obtained;
c) depositing a thin metallic layer by thermal evaporation or physical vapor deposition, optionally under an oblique angle, onto the surface obtained in step (b), thus obtaining interruptions in the metallic layer which are at least partially located at the grooves or ditches introduced in step (a);
d) depositing another layer of high refractive index material onto said interrupted metallic layer of step (c);
e) covering the layer of high refractive index material obtained in step (d) with one or more layers of a translucent or transparent dielectric material; and optionally
f) depositing an antireflex layer onto the surface obtained in step (e).

28. A method for manufacturing a translucent or transparent film or sheet according to claim 17, which method comprises
a) providing a suitable film or sheet substrate (1);
b) depositing a layer of high refractive index material onto at least one surface of said substrate;
c) depositing a thin metallic layer onto the surface obtained in step (b);
d) introducing interruptions into the metallic layer by removal of 1 to 30% of the metallic layer area with a periodicity from the range 50 to 800 nm while retaining 70 to 99% of the metallic layer area essentially unmodified, for example by plasma etching, embossing, cutting or punching;
e) depositing another layer of high refractive index material onto said interrupted metallic layer of step (d);
f) covering the layer of high refractive index material obtained in step (e) with one or more layers of a translucent or transparent dielectric material; and optionally
g) depositing an antireflex layer onto the surface obtained in step (f).

29. The film or sheet according to claim 17, wherein the substrate (1) and/or the further layer (5) are polymeric materials or glass.

30. The window pane, glass facade element or solar panel of claim 25, wherein the substrate comprises a flat or bent polymer film or sheet, or glass sheet, or a polymer film or sheet and a glass sheet.

31. A method for reducing the transmission of solar IR radiation from the range 700 to 1200 nm, through a transparent element such as a polymer film, plastic screen, plastic sheet, plastic plate, glass screen, especially of a window, architectural glass element or solar panel, which method comprises integrating film or sheet according to claim 17 into said transparent element.

32. A method for reducing entry of IR radiation through a window or glass façade element into interior space of a building, or for reducing heat uptake of a solar panel or photovoltaic cell, comprising incorporating the film or sheet according to claim 17 into said window or glass façade element or solar panel or photovoltaic cell.
